(19) United States
(12) Patent Application Publication
(10) Pub. No.: US 2025/0255050 A1
(43) Pub. Date: Aug. 7, 2025

(54) WAVELENGTH CONVERTER AND LED DIE FOR CORRECTING EDGE COLOR SHIFT AND METHODS OF MANUFACTURE

(71) Applicant: LUMILEDS LLC, San Jose, CA (US)

(72) Inventors: Florent Grégoire Monestier, Kerkrade (NL); Antonio Lopez-Julia, Aachen (DE); Niels Jeroen van der Veen, Geldrop (NL)

(73) Assignee: LUMILEDS LLC, San Jose, CA (US)

(21) Appl. No.: 18/434,502

(22) Filed: Feb. 6, 2024

(51) Int. Cl. H01L 33/50; H01L 25/075; H01L 33/44

(52) U.S. Cl. CPC H10H 20/8512; H01L 25/0753; H10H 20/84; H10H 20/0361

(57) ABSTRACT

An LED die, a wafer of LED dies, and methods of manufacture are described. The LED die includes a semiconductor stack configured to emit a pump light when energized and a wavelength converter over the semiconductor stack. The wavelength converter converts some of the pump light to a converted light having a differing color. A spatially inhomogeneous dichroic filter on the wavelength converter, which at least one of: increases reflection of the pump light in special regions of peak luminance, increases reflection of the converted light in spatial regions of low luminance, increases transmission in at least a portion of the converted light in spatial regions of peak luminance, or increases transmission of the pump light in spatial regions of low luminance.

### BACKGROUND

Light-emitting diodes (LEDs) are increasingly more used in lighting applications, such as automotive lighting systems or general illumination applications, for example, instead of more conventionally used filament lights. In some applications, shaped surface luminance LEDs may be used to control the luminance distribution of light emitted by the LEDs over the surface area of such LEDs. The luminance distribution can be represented in graph form in a luminance map, where a series of peaks and valleys may define the regions of the LED's surface area where the luminance is higher than average or lower than average, with the highest points being termed “peak luminance.”

### SUMMARY

An LED die, a wafer of LED dies, and methods of manufacture are described. The LED die includes a semiconductor stack configured to emit a pump light when energized and a wavelength converter over the semiconductor stack. The wavelength converter converts some of the pump light to a converted light having a differing color. A spatially inhomogeneous dichroic filter on the wavelength converter, which at least one of: increases reflection of the pump light in special regions of peak luminance, increases reflection of the converted light in spatial regions of low luminance, increases transmission in at least a portion of the converted light in spatial regions of peak luminance, or increases transmission of the pump light in spatial regions of low luminance.

### BRIEF DESCRIPTION OF THE DRAWINGS

A more detailed understanding can be had from the following description, given by way of example in conjunction with the accompanying drawings wherein:

FIG. 1 is a diagram of a luminance map, a v′ map and a cross section v′, for a uniform die.;

FIG. 2 is a diagram of an example ESL LED;

FIG. 3 is a diagram of a luminance map, a v′ map, and a cross section v′, for an edge shift luminance die;

FIG. 4 is a diagram of a luminance map, a v′ map, and a cross section v′, for a CPL die;

FIG. 5 is a cross-sectional view of an LED having a wavelength converter with low transparency;

FIG. 6A is a diagram of an example DCF covering the entirety of the LEA of an underlying wavelength converter;

FIG. 6B is a graph of computed transmittance versus visible wavelength for various angles of incidence for the blue DCF of FIG. 6A;

FIG. 7A is a diagram of a conventional AR coating covering the entirety of the LEA of an underlying wavelength converter;

FIG. 7B is a graph of computed transmittance versus visible wavelength for various angles of incidence for the AR coating of FIG. 7A;

FIG. 8 is a diagram of an ESL die with an AR coating covering the full converter area and a luminance map, a v′ map, and a cross section v′ for the ESL die;

FIG. 9 is a diagram of an ESL die with blue DCF applied only to the area corresponding to peak luminance and a luminance map, a v′ map and a cross section v′ for the ESL die;

FIG. 10 is a diagram of an ESL die with a blue DCF applied approximately only to the area corresponding to peak luminance and a luminance map, a v′ map, and a cross section v′, for the ESL die;

FIG. 11 is a diagram of a CPL die with a blue DCF applied approximately only to the area corresponding to peak luminance, and a luminance map, a v′ map, and a cross section v′, for the CSL die;

FIG. 12A is a flow diagram of an example method of depositing DCF and AR coatings on a wavelength converter;

FIG. 12B is a top view of an example wafer showing the DCF and coatings at two points during the method of depositing illustrated in FIG. 12A;

FIG. 13A is a flow diagram of another example method of depositing DCF and AR coatings on a wavelength converter;

FIG. 13B is a diagram showing top and cross-section views of a first example LED die manufactured according to the method of FIG. 13A; and

FIG. 14 is a diagram showing cross-section views of an LED die, top views of the LED die, and top views of a 3×3 wafer resulting from patterning in larger blocks according to three different arrangements (a), (b) and (c).

### DETAILED DESCRIPTION

Examples of different light illumination systems and/or light emitting diode (“LED”) implementations will be described more fully hereinafter with reference to the accompanying drawings. These examples are not mutually exclusive, and features found in one example may be combined with features found in one or more other examples to achieve additional implementations. Accordingly, it will be understood that the examples shown in the accompanying drawings are provided for illustrative purposes only and they are not intended to limit the disclosure in any way. Like numbers refer to like elements throughout.

It will be understood that, although the terms first, second, third, etc. may be used herein to describe various elements, these elements should not be limited by these terms. These terms may be used to distinguish one element from another. For example, a first element may be termed a second element and a second element may be termed a first element without departing from the scope of the present invention. As used herein, the term “and/or” may include any and all combinations of one or more of the associated listed items.

It will be understood that when an element such as a layer, region, or substrate is referred to as being “on” or extending “onto” another element, it may be directly on or extend directly onto the other element or intervening elements may also be present. In contrast, when an element is referred to as being “directly on” or extending “directly onto” another element, there may be no intervening elements present. It will also be understood that when an element is referred to as being “connected” or “coupled” to another element, it may be directly connected or coupled to the other element and/or connected or coupled to the other element via one or more intervening elements. In contrast, when an element is referred to as being “directly connected” or “directly coupled” to another element, there are no intervening elements present between the element and the other element. It will be understood that these terms are intended to encompass different orientations of the element in addition to any orientation depicted in the figures.

Relative terms such as “below,” “above,” “upper,”, “lower,” “horizontal” or “vertical” may be used herein to describe a relationship of one element, layer, or region to another element, layer, or region as illustrated in the figures. It will be understood that these terms are intended to encompass different orientations of the device in addition to the orientation depicted in the figures.

Having described the embodiments in detail, those skilled in the art will appreciate that, given the present description, modifications may be made to the embodiments described herein without departing from the spirit of the inventive concept. Therefore, it is not intended that the scope of the invention be limited to the specific embodiments illustrated and described.

Analysis of some automotive system optics suggests that a shaped surface luminance LED, where the peak luminance resides in the center of the LED, provides the best system performance for system optics with a total internal reflectance (TIR) lens. On the other hand, LED surface luminance with a gradient from one side to another side may provide the best system performance for system optics with a reflector. This is by contrast to a uniform die where the surface luminance is more evenly disbursed. System optical performance may be evaluated via a system optics figure of merit (FOM), which may evaluate both the intensity and quality of light distribution on the road. In the embodiments described herein, an LED die with a center peak luminance distribution may be referred to as a center peak luminance (CPL) die, and an LED die with edge shift luminance may be referred to as an edge shift luminance (ESL) die. In general, a die with shaped luminance profile may be defined as a die where the luminance averaged over an area equal to at least ten percent (10%) of the entire light emitting area deviates more than twenty percent (20%) of the mean luminance averaged over the entire light emitting area. The area where luminance deviates the most may be referred to as the peak luminance.

While shaped surface luminance LEDs can be advantageous for certain applications, as discussed above, such LEDs can also cause potentially unwanted color variation in the light emitted from the LED. Such variation may be assessed by analyzing, for example, system optical metrics, such as efficacy (which may be determined by Vf and LED flux), color over source (CoS) variation, and/or color over angle and thermal resistance. Strong CoS variation may be particularly important as it can lead to dramatic and unpleasant color variation of the projected light on the road.

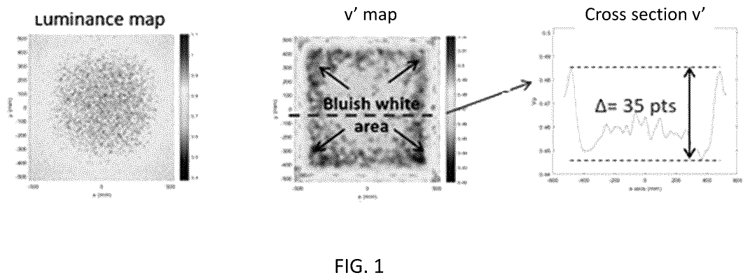

FIG. 1 is a diagram of a luminance map, a v′ map, and a cross section v′, for a uniform die. The uniform die may be, for example, a standard 1 mm² uniform die. In the example illustrated in FIG. 1, for the uniform die, the luminance map is largely centered with respect to the surface area of the LED (i.e., peak intensity is largely centered in the die), and there are relatively small variations v′ in light intensity.

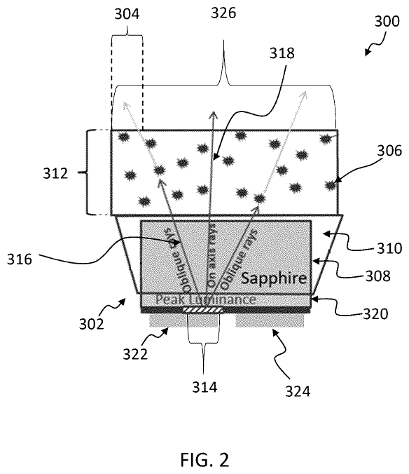

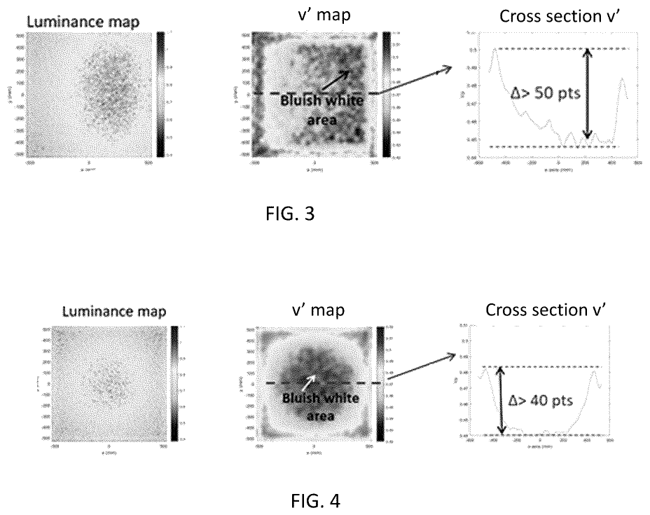

FIG. 2 is a diagram of an example ESL LED 300. In the example illustrated in FIG. 2, the LED 300 includes an LED die 308, which may include epitaxial layers 320 on a substrate 308, such as a sapphire substrate. A wavelength converter 312 is disposed over the LED die 302 and may be secured to the LED die 302 such as via an adhesive 310. A top surface of the wavelength converter 312 may be referred to as the light-emitting area (LEA) 326 where light is emitted from the LED 300. In the example illustrated in FIG. 3, the LEA 326 takes up the entirety of the top surface of the wavelength converter 312, although one of ordinary skill in the art will understand that the LEA in practice will likely take up less than the entirety of the top surface. Conductive contacts 322 and 324 may be disposed on or near a bottom surface of the LED die 308, which may be used to provide current to drive the LED 300, from an external power source (not shown), to power it on and off. The conductive contacts 322, 324 may be shaped and located in such a manner as to promote current injection into specific parts of the die.

In some embodiments, a highly reflective material (not shown in FIG. 2), such as an optical side coat, may be placed around the side surface or side surfaces of the LED die 302 and the wavelength converter 312 to avoid light emission from the LED 300 in areas other than the LEA 326. In the example illustrated in FIG. 2, the wavelength converter 312 overhangs the LED die 302 in an overhang area 304. The wavelength converter 312 may overhang the LED die 302 on all sides. This overhang may be included to avoid having blue rays that do not pass through the platelet due to misalignment of the platelet.

FIG. 2 illustrates an edge color shift effect that occurs in the overhang area or areas 304. As can be seen in FIG. 3, the LED die 302 emits on axis rays 318 and oblique rays 316. The on axis rays may pass through the wavelength converter 312 unconverted or via a short path to the LEA, and the oblique rays may be absorbed by phosphor particles 306 in the wavelength converter 312 and/or re-emitted as rays of a different color and/or via a. In the peak luminance area 314, for example, due to geometric conditions, the LED die 320 emits many more oblique rays that travel a longer distance through the wavelength converter 312 than on axis rays 318. This may result in an edge color shift phenomena where the light emitted through the wavelength converter 312 may appear more yellow to the viewer in areas away from the peak luminance area 314 than in the peak luminance area 314. Accordingly, LEDs, such as the LED 300 illustrated in FIG. 2, may have the strong disadvantage of having high CoS variation.

This edge color shift phenomena tends to occur in all shaped surface luminance LEDs based on non-uniform current distribution, which may also have the disadvantage of strong CoS variation. Similar to the LED 300 illustrated in FIG. 3, for such shaped surface luminance LEDs based on non-uniform current distribution, light emitted via the part away from the peak luminance area may appear more yellow than light emitted via the peak luminance area.

FIG. 3 is a diagram of a luminance map, a v′ map, and a cross section v′, for an edge shift luminance die. In comparison with the diagram provided in FIG. 1, the edge shift luminance die has a minimum of 50 points variation of v′ between the peak luminance area and the platelet overhang area.

FIG. 4 is a diagram of a luminance map, a v′ map, and a cross section v′, for a CPL die. As compared to the same diagrams for the uniform and ESL dies, the CPL die has a minimum of 40 points variation v′.

It should be noted that color variation over source will depend directly on luminance uniformity and associated current uniformity. The more the current uniformity over the LEA of the LED is, the higher will be the CoS variation. Unlike the uniform die, the most white-bluish area of the ESL and CPL dies matches with the peak luminance area. This is very critical for system optical performance as this peak luminance area will contribute the most to the cut-off color in a low beam automotive optical system or to the peak intensity in an automotive high beam optical system.

Conventional shaped luminance LEDs are designed to promote current injection into specific parts of the LED die. This method, therefore, leads to strong CoS variation, as shown in FIGS. 3 and 4, and described above, as oblique rays emitted near the peak luminance area will be more converted than rays emitted in the center of the die.

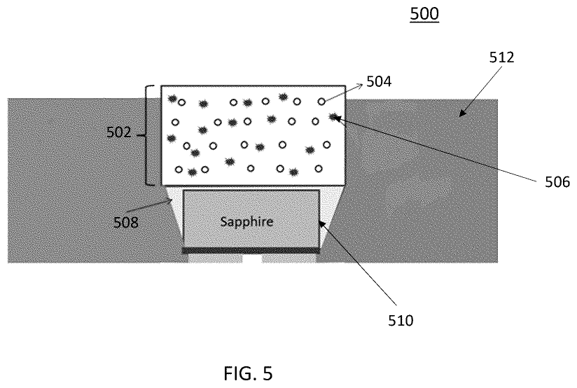

FIG. 5 is a cross-sectional view of an LED 500 having a wavelength converter 502 with low transparency. As illustrated in FIG. 5, a conventional means of solving the strong CoS variation in conventional shaped luminance LEDs may be to use a wavelength converter 502 that is thick and has low transparency by providing a high density of scattering air pores 504. Such high density of scattering air pores 504 may scatter light in all directions, resulting in better color mixing of light emitted via the LEA. All other parts of the LED 500 may be the same as, or similar to, the LED 300 illustrated in FIG. 2. For example, the wavelength converter 504 may also include phosphor particles 506, and the wavelength converter may be disposed over an LED die 510, which may be the same as, or similar to, the LED die 302 of FIG. 2. The wavelength converter 502 may be adhered to the LED die 510 via an adhesive 508. While the LED 500 may slightly improve edge color shift by providing better color mixing, the LED 500 may also reduce optical flux and surface luminance as interaction with the optical side coat (not shown but described above with respect to FIG. 3) may be higher. While the substrate of the LED die 510 is labeled sapphire in FIG. 5, any suitable type of substrate can be used for the LED die 510 as would be understood by one of ordinary skill in the art.

In the example illustrated in FIG. 5, the wavelength converter 502 is completely covered on all side surfaces by a diffuse, scattering, optical side coat 512. This may reduce the color shift as almost no light will be emitted via the overhang area. However, such design will also reduce optical flux and requires a thick wavelength converter 502 to be sure that no light is emitted above the overhang area. In some cases, for example, the wavelength converter may be as thick as approximately 200 μm or more.

Another method that may be used to solve color over angle or color over source variation may be to use a blue dichroic filter coating over the full converter area. A dichroic filter (DCF) is typically made by stacking pairs of non-absorbent ceramic material with high and low refractive indexes. Each layer of the filter may have an optical thickness lower than a visible wavelength to obtain a filter with higher blue reflectivity than the rest of the visible spectrum. Typically, the wavelength domain with higher reflectivity (e.g., with lower transmission) overlaps the emission spectrum of the blue pump light.

Color correction with DCF coating over the full converter area relies on higher reflection of blue rays that will subsequently be converted to yellow. This color correction method may have a limited impact on optical flux as most of the reflected blue rays will not be lost. However, it shifts the v′ of the die further away from the peak luminance. Accordingly, this may not work to correct strong COS variation of shaped surface luminance.

In embodiments described herein, a patterned blue dichroic filter (DCF) may be applied approximately only on the area corresponding to the peak luminance area, plus or minus any tolerances, for example. An anti-reflection (AR) coating may also be deposited on an area without DCF, for example to limit flux drop penalty and improve the color transition between the area with DCF and the area without DCF. As described in detail below, in some embodiments, the DCF may be patterned.

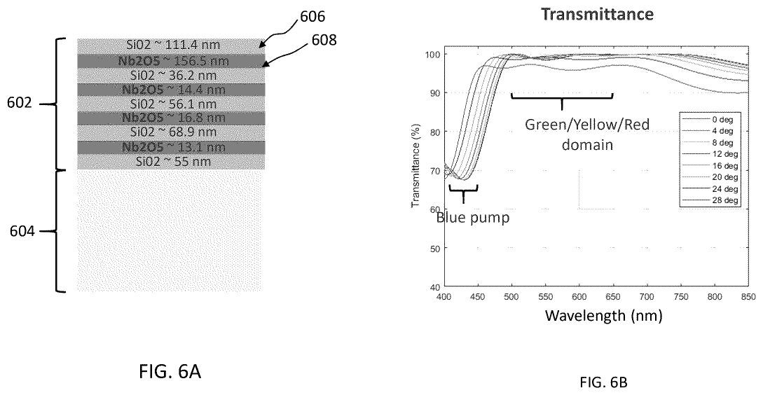

FIG. 6A is a diagram of an example DCF 602 covering the entirety of the LEA of an underlying wavelength converter 604. In the example illustrated in FIG. 6A, the example DCF 602 includes 9 layers. DCFs, such as the DCF 602 illustrated in FIG. 6A, may be made of quarter or half wavelength optical thickness that promotes constructive and destructive optical interferences at the desired wavelengths and desired angles. A typical material with a low refractive index is SiO2, and a typical material with a high refractive index may be Al₂O3, amorphous AlOx, Nb₂O₅, by way of example only. In the example illustrated in FIG. 6A, for example, the DCF 602 includes alternating layers of SiO₂ 606 and Nb₂O₅ 608. Each layer 606, 608 may have a different optical thickness, as indicated in the example illustrated in FIG. 6A. The wavelength converter 604, in the example illustrated in FIG. 6, is a YAG garnet matrix doped with Ce.

FIG. 6B is a graph of computed transmittance versus visible wavelength for various angles of incidence for the blue DCF 602 of FIG. 6A. The angle of incidence is in the incident medium that is a Garnet (Y, Gd)₃Al₅O₁₂ matrix doped with Ce.

As can be seen from the graph in FIG. 6B, normal transmittance in the blue pump region is ˜70%, so 27 to 30 points lower than in the yellow and red region (>98%). Normal transmittance is >98.5% starting from 500 nm. Transmittance is shown for angles of incidence between 0 and TIR angle (typically equal to 32.8° at 500 nm at interface YAG garnet/Air). Yellow-Red transmittance is more than 97% for angle of incidence in a YAG garnet matrix lower than 20°. Similar performances (but slightly lower) can be obtained with a 5 layer blue DCF. The example illustrated in FIG. 6A has 9 layers, but it is only one example for illustration. For fair comparison, performances of the die with a patterned DCF coating may be compared with performances of a conventional die with an AR coating.

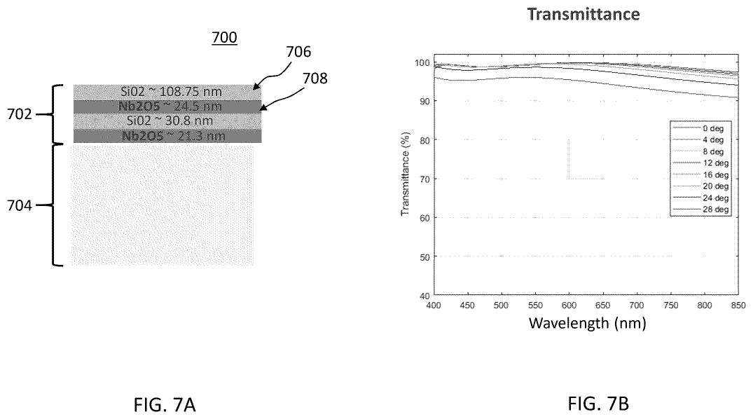

FIG. 7A is a diagram of a conventional AR coating 702 covering the entirety of the LEA of an underlying wavelength converter 704. In the example illustrated in FIG. 7A, the AR coating 702 includes 4 layers. In the example illustrated in FIG. 7A, for example, the AR coating 702 includes alternating layers of SiO₂ 706 and Nb₂O₅ 708. Each layer 706, 708 may have a different optical thickness, as indicated in the example. The wavelength converter 704, in the example illustrated in FIG. 7, is a YAG garnet matrix doped with Ce, similar to FIG. 7A. FIG. 7B is a graph of computed transmittance versus visible wavelength for various angles of incidence for the AR coating 702 of FIG. 7A.

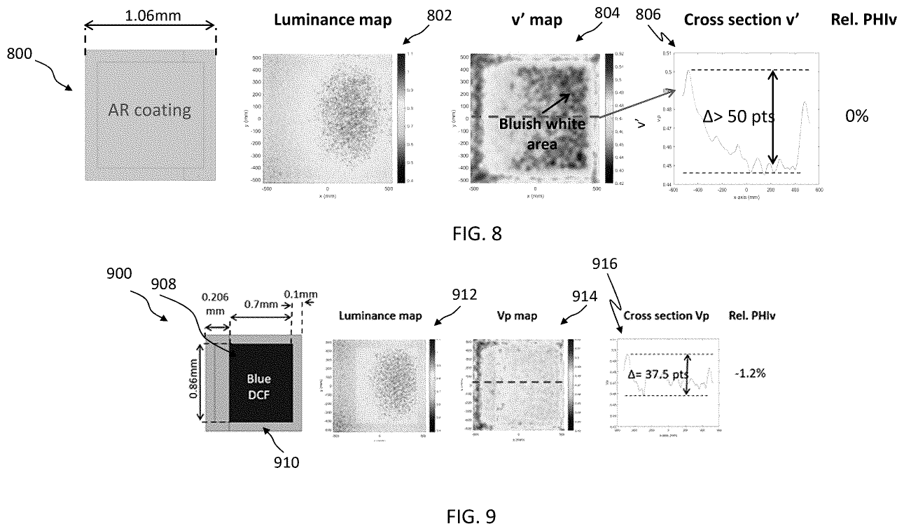

FIG. 8 is a diagram of an ESL die 800 with an AR coating covering the full converter area (1.12 mm² in the illustrated example) and a luminance map 802, a v′ map 804 and a cross section v′ 806 for the ESL die 800.

FIG. 9 is a diagram of an ESL die 900 with a blue DCF 908 applied only to the area corresponding to peak luminance and a luminance map 912, a v′ map 914 and a cross section v′ 916 for the ESL die 900. In the example illustrated in FIG. 9, the area 910 of the die that is not covered by the blue DCF 908 has no coatings applied to it. In the example illustrated in FIG. 9, the blue DCF 908 covers 0.602 mm² of the 1.06 mm² die and may be approximately 0.1 mm away from the platelet converter edge close to peak luminance.

As can be seen from FIG. 9, v′ near the peak luminance is 0.46 instead of 0.45 resulting in ˜10 points reduction of v′ variation over source. However, the flux penalty, compared with the die 800 illustrated in FIG. 8 with the AR coating covering the full area, is around 1.2%. Furthermore, the surface luminance transition between the area with and without blue DCF is not smooth because the transmission of the blue DCF in the yellow-green wavelength range is a few percent higher than the area without blue DCF.

In some embodiments, angular dichroic coatings may be used instead of wavelength dichroic filters. For example, reflectivity of rays with incidence angles in the converter medium lower than 8 degrees will be higher than reflectivity of rays with incidence angles between 8 degrees and the TIR angle. In some embodiments, the blue DCF will be dichroic in both wavelength and scattering angle.

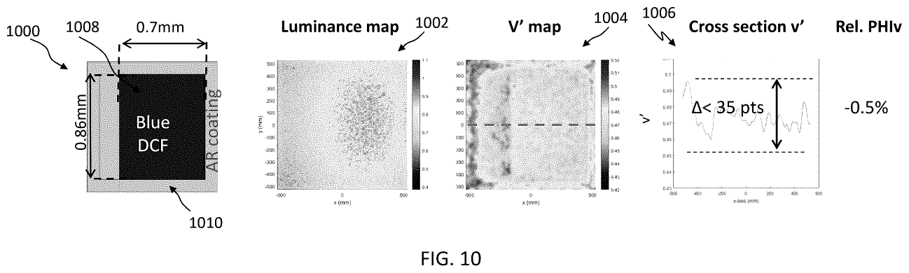

FIG. 10 is a diagram of an ESL die 1000 with blue DCF 1008 applied approximately only to the area corresponding to peak luminance and a luminance map 1002, a v′ map 1004 and a cross section v′ 1006 for the ESL die 1000. In the example illustrated in FIG. 10, an AR coating 1010 covers the remaining area of the ESL die that the blue DCF 1008 does not cover. In the example illustrated in FIG. 10, the blue DCF covers 0.602 mm² of the 1.06 mm² die. With this configuration, flux penalty compared to the die 800 in FIG. 8 with the full area coverage AR, is only 0.5%, and v′ variation is reduced to 35 points, which is similar to the uniform die (compare FIG. 1). Furthermore, the surface luminance map provided in FIG. 10 shows no discontinuities. By way of example, as a basic design rule, it can be considered that a blue DCF should cover at least the area where v′ is lower than 0.468. Accordingly, it can be seen that using an AR coating on the areas of an ESL die without blue DCF will help to reduce the v′ of the white-yellowish edge rim area as more blue will be transmitted with a large band AR coating.

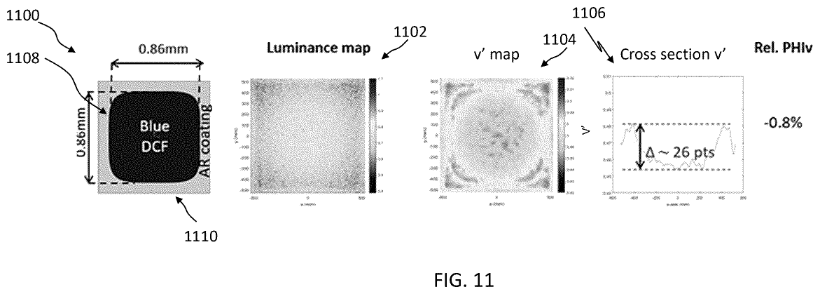

FIG. 11 is a diagram of a CPL die 1100 with blue DCF 1108 applied approximately only to the area corresponding to peak, and a luminance map 1102, a v′ map 1104, and a cross section v′ 1106 for the CSL die 1100. In the example illustrated in FIG. 11, an AR coating 1110 covers the remaining area of the CSL die 1100 that the blue DCF 1108 does not cover. In the example illustrated in FIG. 11, the blue DCF covers 0.7396 mm² of the approximately 1 mm² die. As with the ESL die, v′ variation over source is strongly reduced by more than 15 points, and flux penalty is less than 1% compared to the die 800 in FIG. 8 with the full LEA area coverage AR. Accordingly, the embodiments described herein can apply to all types of shaped surface luminance dies, including both ESL and CPL dies.

DCF and AR coating layers can be deposited, for example, by sputtering, atomic layer deposition (ALD) or plasma enhanced chemical vapor deposition (PECVD). PECVD may work particularly well as the deposition time may be lower and smoother than sputtering. Materials used for PECVD may include, for example, Nb₂O5, SiO2, etc. Materials used for ALD may include Al2O3, HfO2, TiO2 and Ta2O5. Deposition thickness for DCF and AR coatings may vary from approximately 1 nm to approximately 300 nm. The DCF and AR coatings may be deposited on the wafer level on the wavelength converter to maximize the yield and takt time.

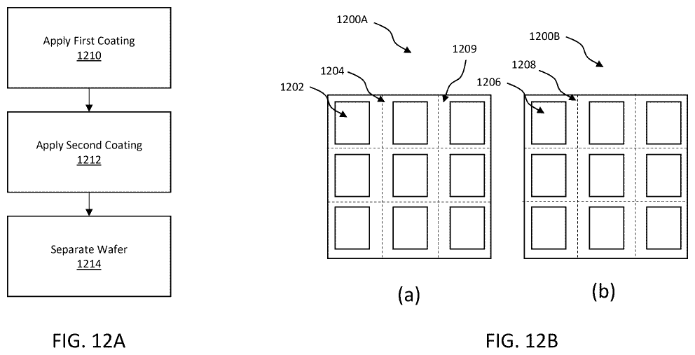

FIG. 12A is a flow diagram of an example method of depositing DCF and AR coatings on a wavelength converter. FIG. 12B is a top view of an example wafer 1200A, 1200B showing the DCF and coatings at two points during the method of depositing illustrated in FIG. 12A.

In the example illustrated in FIG. 12A, a first coating may be applied to a wavelength converter (1210). The wavelength converter may be either a wavelength converter platelet or an LED die with a wavelength converter already deposited at this stage in the manufacturing of process. To apply the first coating, a mask (e.g., a masking tape) may be applied to a top surface (e.g., light emitting surface of an assembled LED die) of the wavelength converter in areas on which the first coating is not to be applied.

FIG. 12B (a) shows a wafer 1200A after the first coating is deposited. In the example illustrated in FIG. 12B, the first coating is the AR coating. A masking tape 1202 has been deposited on areas where the DCF is to be applied during the next phase of the method. The AR coating 1204 has been applied to the wafer 1200A and adheres to the wavelength converter (not visible in FIG. 12B) in regions where the masking tape is not.

A second coating may be applied to the wavelength converter (1200B). To apply the second coating, the mask applied in 1210 may be removed (e.g., by pealing of the masking tape). Another mask (e.g., a masking tape) may be applied to the top surface of the wavelength converter with the first coating already applied.

FIG. 12B (b) shows a wafer 1200B after the second coating is deposited. In the example illustrated in FIG. 12B, the second coating is the blue DCF coating. A masking tape 1208 has been deposited on areas where the AR coating adhered in 1210. The DCF coating 1206 has been applied to the wafer 1200B and adheres to the wavelength converter (not visible in FIG. 12B). The blue DCF coating 1206 has been applied to the wafer 1200B and adheres to the wavelength converter (not visible in FIG. 12B) in regions where the masking tape is not. The other mask may then be removed, resulting in a wafer of 9 platelets or dies 1209.

The wafer of 9 platelets or dies may then be separated into 9 LED dies. This may be done, for example, by dicing, sawing, or laser cutting, to name a few examples.

While the AR coating is applied first in the example described above, the blue DCF coating can be applied in 1210, and the AR can be applied in 1212, in some embodiments. Additionally, while a masking tape is used to mask the wavelength converter in both application steps 1210 and 1212, other materials or processes can be used to mask the wavelength converter. For example, the first coating could be shadowed with a photolithography process (instead of a mask) in 1212.

To simplify the deposition process, it is possible for some of the layers in both the AR and blue DCF areas to be same. In this way, at least one masking step can be eliminated from the process.

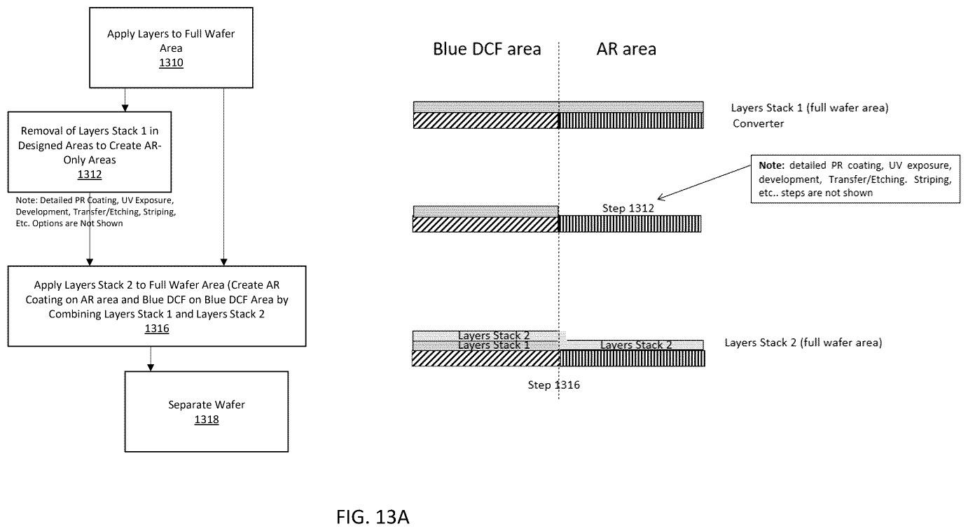

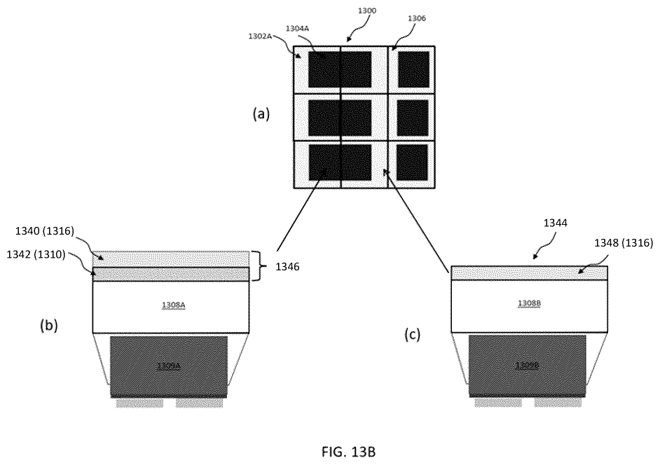

FIG. 13A is a flow diagram of another example method of depositing DCF and AR coatings on a wafer. In the example illustrated in FIG. 13A, layers may be deposited on the full wafer area (1310). As explained in more detail below, the layers deposited in 1310 can be can be either the full AR stack or the full blue DCF stack. If the full blue DCF stack is deposited on the full wafer area in 1310, areas of the deposited layers that are to be covered by the blue DCF may be masked and an etch applied to the wafer to etch the DCF stack down to the wavelength converter (1312), resulting essentially in cavities in the blue DCF where the AR coating is to be applied. The AR coating may then be applied to the full wafer area (1316), and the wafer may be separated into individual platelets or dies (1318).

FIG. 13B is a diagram showing top (a) and cross-section views (b) and (c) of a first example LED die manufactured according to the method of FIG. 13A. In cross-section view (b), an LED die is illustrated. The illustrated LED die includes epitaxial layers 1309, a wavelength converter 1308 over and/or on the epitaxial layers 1309, and the full DCF stack 1346, which includes the layers stack 1 and layers stack 2 described above with respect to FIG. 13A. The full DCF stack 1346 is shown as blue DCF 1304A in the top view (a). In cross-section view (c), the entire layers stack 1 has been removed (e.g., by etching) and replaced with the AR layers 1348. Although not labeled in FIG. 13B, an AR coating has been applied to the entire wafer top surface, and some remains on top of the blue DCF 1304.

Returning to FIG. 13A, if only the AR stack is deposited on the full wafer area in 1310, the areas 1302A in FIG. 13B can be masked, and additional layers can be deposited on the wafer (1316) prior to separation of the die (1318). Returning now to FIG. 13B, side view (c) can be seen as the result of the first deposition step 1310 with just the AR stack 1348. Side view (b) can be seen as the result of the second deposition step 1316 with the entire DCF stack 1346, which includes the AR layers 1342 deposited in 1310 and the additional layers 1340 deposited in 1316.

While not intended to be limiting, the wavelength converter described herein may be a yellow converter. Examples materials that can be used to make the wavelength converter may include one or more of Garnets (Y, Gd)3Al5O12 doped with Ce (an oxide phosphor); Eu(II) doped nitridosilicate (M2Si5N8) and oxonitridosilicate materials (MSi2O2N2) (wherein M=alkaline earth); a silicone matrix filled with phosphor materials (blends) of garnets (see above), Eu-doped Nitrosilicates, SLA, SLAO, and other phosphors; and/or a glass matrix filled with any one or more of the above mentioned phosphors.

In practice, the various patterning methods described above may be complicated to realize. To reduce the yield loss during patterning, reduce the impact of masking/patterning tolerances, and reduce the impact of mask shadowing, the size of patterned areas may be maximized. This may be done by, for example, shifting the location of the blue DCF pattern to at least one edge of the die to avoid the requirement to deposit many small, blue, DCF areas that are disconnected from the die edges (also commonly referred to as islands). This will enable the blue DCF areas on neighboring dies on the wafer to be deposited in larger blocks to provide a larger patterning window. If the DCF area reaches 3 edges of the die, it will allow for patterning of full columns (stripes) on the wafer.

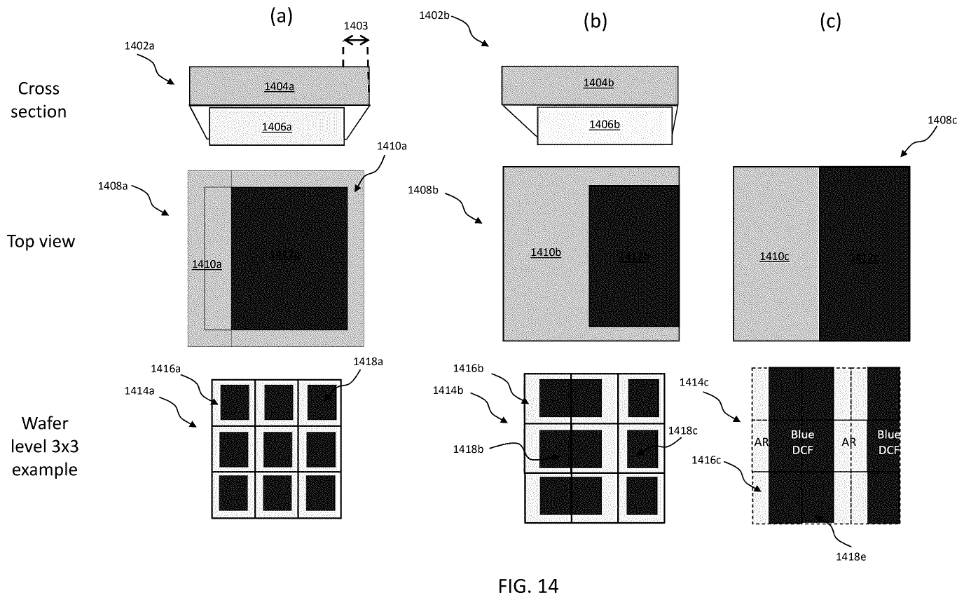

FIG. 14 is a diagram showing cross-section views of an LED die, top views of the LED die, and top views of a 3×3 wafer resulting from patterning in larger blocks according to three different arrangements (a), (b) and (c).

In FIG. 14 (a), in the cross-section view, an LED die 1402a includes a wavelength converter 1404a over and/or on an epitaxial stack 1406a. As can be seen, the epitaxial stack 1406a is approximately centered under the wavelength converter 1404a with an overhang area 1403 overhanging the epitaxial stack 1406a. In FIG. 14 (a), in the top view, the blue DCF 1412a is provided over a large portion of the top surface 1408a of the wavelength converter 1404a and is surrounded by an area of AR coating 1410a. While the blue DCF area 1412a takes up much of the top surface 1408a, it is slightly off center such that only areas of the top surface 1408a that correspond to peak luminance can be covered by the blue DCF 1412a. In FIG. 14 (a), in the wafer level view, the wafer 1414a includes 9 LED dies, each including a blue DCF 1418a and an AR coating 1416a.

In FIG. 14 (b), in the cross-section view, an LED die 1402b includes a wavelength converter 1404b over and/or on an epitaxial stack 1406b. As can be seen, the wavelength converter 1410b is shifted to an edge of the epitaxial stack 1406b to shift the peak luminance area closer to the edge of the LED die 1406. In FIG. 14 (b), in the top view, the blue DCF 1412b is also shifted to the edge of the wavelength converter area 1408b, with the AR coating 1410b covering the remainder of the wavelength converter area 1408b. In FIG. 14 (b), in the wafer level view, larger areas of blue DCF 1418b may be deposited over adjacent dies of the wafer 1414b. In a wafer with an even number of dies, all of the blue DCF areas can be deposited as in FIG. 14 (b) top view. In a wafer with an odd number of dies, as illustrated, some of the dies can be configured as shown in FIG. 14 (a) top view. These dies may have smaller blue DCF islands 1418c.

In FIG. 14 (c), the blue DCF 1412c has been shifted to three edges of the wavelength converter area 1408c, as shown in the top view, creating an LED die or converter platelet with half of its LEA covered in the blue DCF 1412c and the other half covered in the AR coating 1410c. In the wafer level view, the simplification of the deposition process can be seen, as the blue DCF 1418e and the AR coating 1416c can be deposited in larger stripes across multiple adjacent LED dies on the wafer 1414c. While a cross section view is not provided for FIG. 14 (c), one of ordinary skill in the art will understand that the LED die can be shifted, if necessary, toward up to three edges of the wavelength converter area 1408c, similar to the embodiment illustrated in FIG. 14 (b).

As alluded to above, on the die level, the blue DCF can be brought to the die edge with minimal impact on color variation by reducing platelet overhang 1403 as the border area with high v′ will be limited. This can be done on 1 side of the die at least, as illustrated in FIG. 14 (b) cross-section view, which would typically be the peak luminance side of an ESL die.

Although features and elements are described above in particular combinations, one of ordinary skill in the art will appreciate that each feature or element can be used alone or in any combination with the other features and elements. In addition, the methods described herein may be implemented in a computer program, software, or firmware incorporated in a computer-readable medium for execution by a computer or processor. Examples of computer-readable media include electronic signals (transmitted over wired or wireless connections) and computer-readable storage media. Examples of computer-readable storage media include, but are not limited to, a read only memory (ROM), a random access memory (RAM), a register, cache memory, semiconductor memory devices, magnetic media such as internal hard disks and removable disks, magneto-optical media, and optical media such as CD-ROM disks, and digital versatile disks (DVDs).

What is claimed is:

1. A light-emitting diode (LED) die comprising:
a semiconductor stack configured to emit a pump light when energized;
a wavelength converter over the semiconductor stack, the wavelength converter configured to convert some of the pump light to a converted light having a differing color;
a spatially inhomogeneous dichroic filter on the wavelength converter, wherein the spatially inhomogeneous dichroic filter is configured to at least one of:
increase reflection of the pump light in spatial regions of peak luminance,
increase reflection of the converted light in spatial regions of low luminance,
increase transmission in at least a portion of the converted light in spatial regions of peak luminance, or
increase transmission of the pump light in spatial regions of low luminance.

2. The LED die of claim 1, wherein the spatial regions of peak luminance have v′ lower than approximately 0.468.

3. The LED die of claim 1, wherein the spatially inhomogeneous dichroic filter includes a blue dichroic filter over the spatial regions of peak luminance and an anti-reflective (AR) coating over the spatial regions of low luminance.

4. The LED die of claim 3, wherein the blue dichroic filter extends to at least one edge of the wavelength converter.

5. The LED die of claim 3, wherein the blue dichroic filter extends to three edges of the wavelength converter.

6. A wafer of a plurality of light-emitting diode (LED) dies, the wafer comprising:
a semiconductor stack configured to emit a pump light when energized;
a wavelength converter over the semiconductor stack, the wavelength converter configured to convert some of the pump light to a converted light having a differing color; and
a spatially inhomogeneous dichroic filter on the wavelength converter, wherein the spatially inhomogeneous dichroic filter is configured to at least one of:
increase reflection of the pump light in spatial regions of peak luminance,
increase reflection of the converted light in spatial regions of low luminance,
increase transmission in at least a portion of the converted light in spatial regions of peak luminance, or
increase transmission of the pump light in spatial regions of low luminance.

7. The wafer of claim 6, wherein the spatial regions of peak luminance have v′ lower than approximately 0.468.

8. The wafer of claim 7, wherein the spatially inhomogeneous dichroic filter includes a blue dichroic filter over the spatial regions of peak luminance and an anti-reflective (AR) coating over the spatial regions of low luminance.

9. The wafer of claim 8, wherein the blue dichroic filter extends to one edge of each pair of adjacent LED dies in the wafer.

10. The wafer of claim 8, wherein, for at least some of the LED dies in the wafer, the blue dichroic filter is islanded.

11. The wafer of claim 8, wherein the dichroic filter forms at least one first stripe across at least 3 LED dies in the wafer, and the AR coating forms at least one second stripe across at least 3 LED dies in the wafer.

12. A method of manufacturing at least one LED die, the method comprising:
obtaining a semiconductor wafer configured to emit light when energized, the semiconductor wafer comprising a wavelength converter and having a light-emitting top surface;
determining one or more spatial regions of the wavelength converter to be covered by a blue dichroic filter based on a luminance map of the at least one LED die such that regions of the semiconductor wafer to be covered by the blue dichroic filter correspond to regions of the LED die that emit light having peak luminance when energized;
applying a plurality of dichroic filter layers to the light-emitting top surface of the wavelength converter;
removing the plurality of dichroic filter layers over areas that are not determined to be covered by the blue dichroic filter; and
applying a plurality of anti-reflective coating (AR) layers to the entire light-emitting top surface to form an inhomogeneous dichroic filter on the wavelength converter.

13. The method of claim 12, wherein the determining comprises:
generating the luminance map, and
determining which areas of the luminance map have v′ lower than 0.468.

14. The method of claim 12, wherein the removing the plurality of dichroic filter layers comprises masking the determined areas, applying an etch to the wafer down to the wavelength converter, and depositing the plurality of AR layers to the entire light-emitting area, filling cavities formed by the etching.

15. The method of claim 14, further comprising separating the wafer into a plurality of LED dies.

16. A method of manufacturing at least one LED die, the method comprising:
obtaining a semiconductor wafer configured to emit light when energized, the semiconductor wafer comprising a wavelength converter;
depositing a plurality of blue dichroic filter layers over a first region of the wavelength converter; and
depositing plurality of anti-reflective (AR) layers over a second region of the wavelength converter, wherein the first region of the wavelength converter overlies a second region of the semiconductor wafer that emits light having peak luminance when energized, and wherein the first and second regions do not overlap.

17. The method of claim 16, wherein the depositing the plurality of blue dichroic filter layers and the plurality of AR layers comprise applying the plurality of dichroic filter layers and the anti-reflective coating layers in stripes over the wafer.

18. The method of claim 16, wherein the depositing the plurality of blue dichroic filter layers comprises applying the plurality of blue dichroic filter in blocks that each covers a region that extends between LEDs in pairs of adjacent LED dies in the wafer.

19. The method of claim 16, further comprising separating the wafer into a plurality of LED dies.
